(19) United States
(12) Patent Application Publication
(10) Pub. No.: US 2009/0206466 A1
(43) Pub. Date: Aug. 20, 2009

(54) SEMICONDUCTOR DEVICE

(75) Inventors: Hiroyuki Shinkai, Kyoto-shi (JP); Hiroshi Okumura, Kyoto-shi (JP)

Correspondence Address: FISH & RICHARDSON P.C.;Citigroup Center, 52nd Floor, 153 East 53rd Street, New York, NY, 10022-4611, US

(73) Assignee: Rohm Co., Ltd., Kyoto (JP)

(21) Appl. No.: 12/357,516

(22) Filed: Jan. 22, 2009

(30) Foreign Application Priority Data
Jan. 25, 2008 (JP) 2008-014441

(51) Int. Cl. H01L 23/52

(52) U.S. Cl. 257/690; 257/E23.141

(57) ABSTRACT

A semiconductor device is provided that can further reduce the thickness of an electronic device and that can reduce its own mounting area and development period. This semiconductor device has a first semiconductor chip and a second semiconductor chip, and is formed in a WLCSP type package. On the upper surface of the first semiconductor chip, an integrated circuit is formed and, in a region other than where it is formed, a recess is formed. An integrated circuit is formed on the second semiconductor chip. The second semiconductor chip is provided in the recess of the first semiconductor chip such that the upper surface of the first semiconductor chip is level with that of the second semiconductor chip.

This application is based on Japanese Patent Application No. 2008-14441 filed on Jan. 25, 2008, the contents of which are hereby incorporated by reference.

### BACKGROUND OF THE INVENTION

1. Field of the Invention

The present invention relates to a semiconductor device. More particularly, the invention relates to a semiconductor device provided with a plurality of semiconductor chips.

2. Description of Related Art

In electronic devices, such as cellular phones and digital still cameras, that are required to be compact and light-weight, semiconductor packages (semiconductor devices) that include a plurality of functions in a single package are incorporated, with a view to reducing the area (mounting area) occupied by the incorporated semiconductor packages. As one example of such semiconductor packages, there is conventionally known a semiconductor package (semiconductor device) including a semiconductor chip formed of a system LSI (large scale integrated circuit) with a plurality of functional regions. In this semiconductor package, on a single semiconductor chip, a plurality of functions, for example, logic, analog, memory, etc. are integrated together. That is, the above-described semiconductor package includes a semiconductor chip which has a plurality of functions integrated on a single chip.

To integrate a plurality of functions such as logic, analog, and memory on a single chip, on the other hand, it is necessary to employ different manufacturing processes for the different functional regions, making up a special manufacturing process as a whole. This, inconveniently, makes the manufacturing process complicated compared with a manufacturing process for logic alone or a manufacturing process for memory alone, and makes it difficult to enhance the performance of each integrated circuit.

Moreover, when logic, analog, memory, etc., which are manufactured by different manufacturing processes, are mixedly integrated on a single semiconductor chip, inconveniently, the optimizing of the semiconductor chip is extremely difficult. This is because an integrated circuit (e.g. a logic circuit) in which voltage reduction is possible and an integrated circuit (e.g. a memory) in which voltage reduction is difficult are mixedly integrated. Thus, the conventional semiconductor package including a semiconductor chip having a plurality of functions integrated on a single chip suffers from increased periods required for development and specification changes of the semiconductor chip (semiconductor package).

In these days, higher performance and versatility are much expected in electronic devices such as cellular phones, and thus the product life cycle is becoming shorter and shorter. Thus, in semiconductor packages incorporated in such electronic devices, the shortening of its development period is sought. On the other hand, in the conventional semiconductor package described above, the shortening of its development period is difficult, and thus it is difficult to meet such expectations.

Thus, as a semiconductor package (semiconductor device) that can reduce the development period while reducing the occupied area (mounting area), there is conventionally known a three-dimensionally stacked semiconductor package (semiconductor device) including a plurality of semiconductor chips formed by separate manufacturing processes respectively and packaged in a state where these semiconductor chips are laid on one another. The plurality of semiconductor chips are electrically connected together via penetrating electrodes and bonding wires.

In the three-dimensionally stacked semiconductor package described above, the plurality of semiconductor chips include, for example, a semiconductor chip in which a logic circuit is formed, a semiconductor chip in which an analog circuit is formed, a semiconductor chip in which a memory is formed, etc.; these semiconductor chips are formed by separate manufacturing processes respectively. Thus, as distinct from in a case where a plurality of functions are integrated on a single chip, it is possible to prevent the manufacturing processes from becoming complicated. It is therefore easy to enhance the performance of each integrated circuit.

Moreover, since integrated circuits are then formed separately by a different manufacturing process on each semiconductor chip, when forming integrated circuits such as logic, analog, and memory, which are formed by different manufacturing processes, it is possible to form each integrated circuit by a manufacturing process optimized separately for each semiconductor chip. Thus, it is possible to optimize the functions of the semiconductor package easily. Accordingly, the development period can be shortened. Moreover, laying the plurality of semiconductor chips on one another into a single package enables the reduction of the area occupied by the semiconductor package. Note that the structure of the three-dimensionally stacked semiconductor device described above is disclosed, for example, in JP-A-2006-5221 Publication.

However, in the conventional three-dimensionally stacked semiconductor package described above, though the mounting area is reduced by laying the plurality of semiconductor chips on one another, this leads to a disadvantage that the semiconductor package becomes thicker. Thus, it makes it difficult to make electronic devices such as cellular phones slimmer.

### SUMMARY OF THE INVENTION

The present invention is devised to solve the above problems, and an object of the invention is to provide a semiconductor device that can cope with increasingly thin electronic devices and that can reduce the mounting area and shorten the development period.

To achieve the above object, a semiconductor device according to one aspect of the invention includes a first semiconductor chip having an integrated circuit part formed on one main surface thereof and a recess formed in a region in that one main surface other than where the integrated circuit part is formed, and a second semiconductor chip having an integrated circuit part formed on one main surface thereof. The second semiconductor chip is disposed inside the recess in the first semiconductor chip such that one main surface of the second semiconductor chip is positioned on the same side as one main surface of the first semiconductor chip.

In the semiconductor device according to one aspect, by providing the recess in the region in the first semiconductor chip other than where the integrated circuit part is formed and disposing (providing) the second semiconductor chip inside the recess as described above, it is possible to prevent the semiconductor device from becoming thicker even when it is provided with a plurality of semiconductor chips. Thus, it is possible to make electronic devices slimmer.

In the semiconductor device according to one aspect, by forming the integrated circuit part separately on each of the first semiconductor chip and the second semiconductor chip as described above, it is possible to form each circuit by a different manufacturing process; thus, as distinct from in a case where separate integrated circuit parts are formed on a single chip (a case where a plurality of functions are integrated on a single chip), it is possible to prevent the manufacturing process from becoming complicated. It is therefore possible to easily enhance the performance of each integrated circuit part and to increase the manufacturing yield. Here, it is possible to employ a manufacturing process optimized separately for each semiconductor chip, and thus it is possible to easily optimize each integrated circuit part. Therefore, with the structure described above, it is possible to shorten its development period and, at the same time, to reduce its development cost. Moreover, with the structure described above, it is possible to change specifications and add functions easily.

Furthermore, in the structure described above, since the second semiconductor chip is disposed (provided) inside the recess in the first semiconductor chip, as in the three-dimensionally stacked semiconductor device, it is possible to reduce the mounting area of (the area occupied by) the semiconductor device.

In the semiconductor device according to one aspect described above, preferably, the second semiconductor chip has a thickness smaller than that of the first semiconductor chip. With this structure, it is possible to easily provide the second semiconductor chip inside the recess in the first semiconductor chip and to easily prevent the semiconductor device from becoming thicker. Thus, it is possible to more easily make electronic devices slimmer.

In the semiconductor device according to one aspect described above, preferably, wiring conductors extending between one main surface of the first semiconductor chip and one main surface of the second semiconductor chip are further included, and the integrated circuit part of the first semiconductor chip and the integrated circuit part of the second semiconductor chip are electrically connected together via the wiring conductors.

In the semiconductor device according to one aspect described above, preferably, the depth of the recess is set such that one main surface of the first semiconductor chip is level with one main surface of the second semiconductor chip. With this structure, it is possible to form a plurality of semiconductor chips like a single semiconductor chip; thus, it is possible to easily prevent the semiconductor device from becoming thicker and to easily reduce the mounting area of (the area occupied by) the semiconductor device. Moreover, with this structure, it is possible to easily fabricate a structure similar to that in which a plurality of integrated circuit parts, which are manufactured by different manufacturing processes, are formed on one main surface of a single semiconductor chip. That is, it is possible to easily fabricate a structure similar to that in which a plurality of functional regions employing different manufacturing processes are formed on a single semiconductor chip. This makes it possible to improve the flexibility in design and to shorten the development period. Moreover, in the structure described above, since one main surface of the first semiconductor chip is level with one main surface of the second semiconductor chip, it is possible to electrically connect the integrated circuit part of the first semiconductor chip and the integrated circuit part of the second semiconductor chip together via the wiring conductors easily.

In the semiconductor device according to one aspect described above, it is preferable that external connection terminals be formed on at least one of one main surfaces of the first semiconductor chip and the second semiconductor chip.

In this case, it is preferable that the external connection terminals be formed on each of one main surface of the first semiconductor chip and one main surface of the second semiconductor chip.

In the semiconductor device according to one aspect described above, preferably, the integrated circuit part of the first semiconductor chip and the integrated circuit part of the second semiconductor chip have different functions from one another. Here, more preferably, the integrated circuit part of the first semiconductor chip and the integrated circuit part of the second semiconductor chip are configured to be functionally related to one another. For example, the integrated circuit part of the first semiconductor chip may be configured with a logic circuit, etc. and the integrated circuit part of the second semiconductor chip may be configured with a memory, etc. With this configuration, it is possible to easily change the specifications of the memory, etc. In addition, by employing a general-purpose semiconductor chip as the second semiconductor chip, it is possible to easily reduce (cut down) the costs for development and manufacturing and to easily reduce the development period.

In the semiconductor device according to one aspect described above, it is preferable that a sealing resin layer be formed on one main surface of the first semiconductor chip and on one main surface of the second semiconductor chip.

In this case, the sealing resin layer may be formed so as to cover at least part of the side surface of the first semiconductor chip.

As described above, according to the present invention, it is possible to easily obtain a semiconductor device that can make electronic devices slimmer, and that can reduce the mounting area and shorten the development period.

### BRIEF DESCRIPTION OF THE DRAWINGS

FIG. 1 is a sectional view of a semiconductor device embodying the present invention.

FIG. 2 is an overall perspective view of the semiconductor device embodying the invention.

FIG. 3 is a plan view of the semiconductor device embodying the invention.

FIG. 4 is a perspective view illustrating the structure of the semiconductor device embodying the invention.

FIG. 5 is a perspective view illustrating the structure of the semiconductor device embodying the invention.

FIG. 6 is a sectional view illustrating a method of manufacturing the semiconductor device embodying the invention.

FIG. 7 is a sectional view illustrating a method of manufacturing the semiconductor device embodying the invention.

FIG. 8 is a sectional view illustrating a method of manufacturing the semiconductor device embodying the invention.

FIG. 9 is a sectional view illustrating a method of manufacturing the semiconductor device embodying the invention.

FIG. 10 is a sectional view illustrating a method of manufacturing the semiconductor device embodying the invention.

FIG. 11 is a sectional view illustrating a method of manufacturing the semiconductor device embodying the invention.

FIG. 12 is a sectional view illustrating a method of manufacturing the semiconductor device embodying the invention.

FIG. 13 is a sectional view illustrating a method of manufacturing the semiconductor device embodying the invention.

FIG. 14 is a sectional view illustrating a method of manufacturing the semiconductor device embodying the invention.

FIG. 15 is a sectional view illustrating a method of manufacturing the semiconductor device embodying the invention.

FIG. 16 is a sectional view illustrating a method of manufacturing the semiconductor device embodying the invention.

FIG. 17 is a sectional view illustrating a method of manufacturing the semiconductor device embodying the invention.

### DETAILED DESCRIPTION OF PREFERRED EMBODIMENTS

An embodiment of the present invention will be described in detail below with reference to the accompanying drawings. In the embodiment below, a description will be given of a case where the invention is applied to a WLCSP (wafer level chip scale package) type semiconductor device.

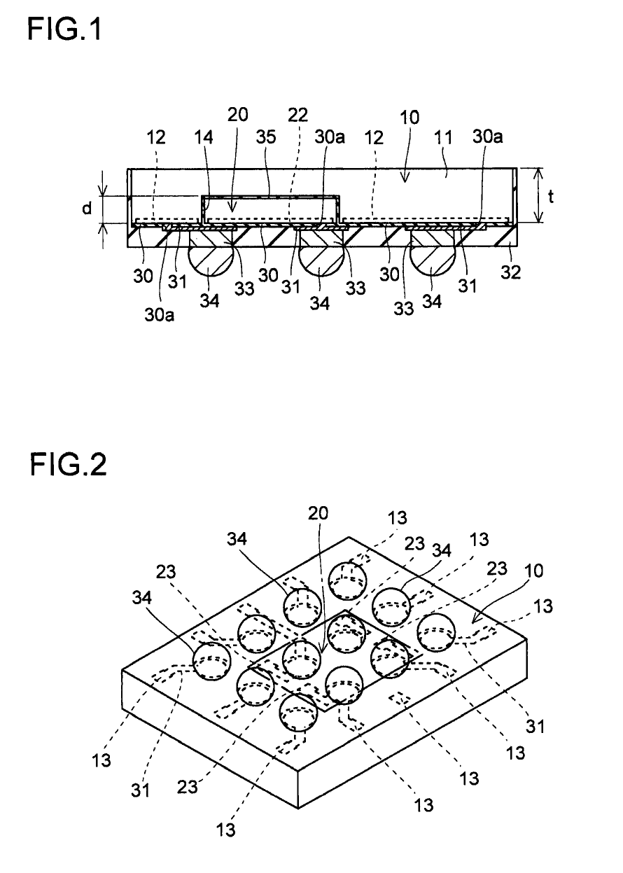

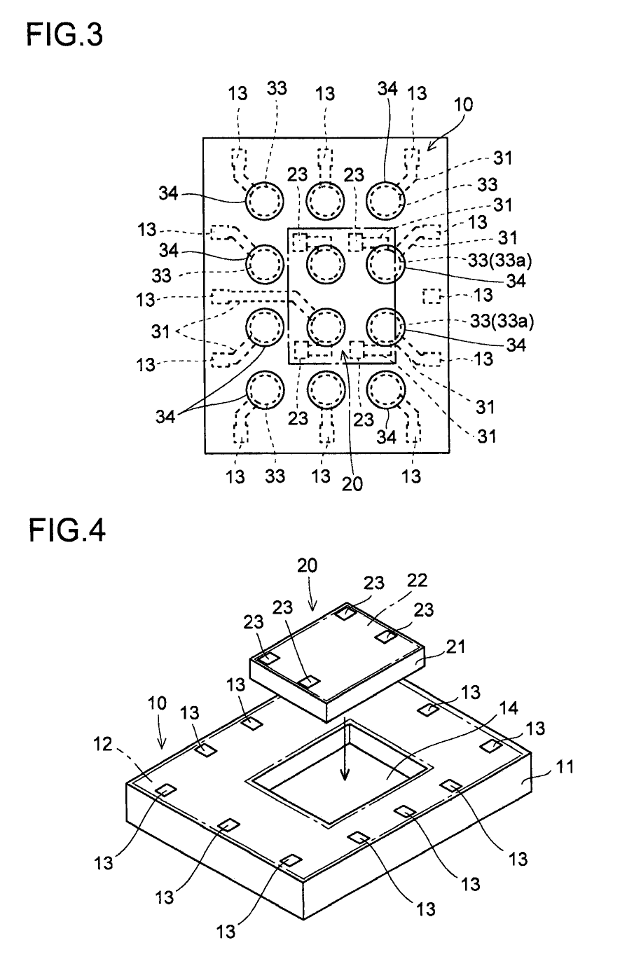

FIG. 1 is a sectional view of a semiconductor device embodying the invention. FIG. 2 is an overall perspective view of the semiconductor device embodying the invention. FIG. 3 is a plan view of the semiconductor device embodying the invention. FIGS. 4 and 5 are perspective views illustrating the structure of the semiconductor device embodying the invention. First, with reference to FIGS. 1 to 5, a description will be given of the structure of the semiconductor device embodying the invention.

As shown in FIG. 1, the semiconductor device according to the embodiment is formed by WLCSP technology and is provided with: a first semiconductor chip 10 and a second semiconductor chip 20; an insulating layer 30 formed on the upper surface (one main surface) of the first semiconductor chip 10 and the second semiconductor chip 20; a plurality of rewiring layers 31 formed on the insulating layer 30; a sealing resin layer 32 formed on the insulating layer 30 and the rewiring layers 31; a plurality of metal posts 33 provided so as to penetrate the sealing resin layer 32 in its thickness direction; and solder balls (bump electrodes) 34 provided on the sealing resin layer and connected electrically one to each metal post 33. Note that the rewiring layers 31 are one example of a “wiring conductor” according to the invention, and the solder balls 34 are one example of an “external connection terminal” according to the invention.

The first semiconductor chip 10 includes a silicon substrate 11, and on the upper surface (one main surface) of the silicon substrate 11, in a predetermined region thereon, an integrated circuit 12 is formed. The integrated circuit 12 is configured with, for example, a logic circuit, etc. As shown in FIG. 4, in an outer peripheral region on the upper surface of the first semiconductor chip 10, a plurality of electrode pads 13 that are electrically connected to the integrated circuit 12 via an unillustrated internal wiring layer are formed. In a topmost layer part of the upper surface of the first semiconductor chip 10, a passivation film (unillustrated) formed of silicon oxide or silicon nitride is formed. In the passivation film, a plurality of openings are formed, and through these openings, the electrode pads 13 are exposed through the passivation film. The first semiconductor chip 10 has a thickness t of approximately 490 μm as shown in FIG. 1, and is formed to have a substantially rectangular shape as seen in a plan view as shown in FIGS. 2 to 4.

As shown in FIGS. 1 and 4, the second semiconductor chip 20 includes a silicon substrate 21, and on the upper surface (one main surface) of the silicon substrate 21, an integrated circuit 22 is formed. The integrated circuit 22, while having a different function from the integrated circuit 12 of the first semiconductor chip 10 described above, is configured with a circuit that is functionally related to it. Specifically, the integrated circuit 22 is configured with a memory, etc. In an outer peripheral region on the upper surface of the second semiconductor chip 20, a plurality of electrode pads 23 (see FIG. 4) that are electrically connected to the integrated circuit 22 via an unillustrated internal wiring layer are formed. In a topmost layer part of the upper surface of the second semiconductor chip 20, a passivation film (unillustrated) formed of silicon oxide or silicon nitride is formed. In the passivation film, a plurality of openings (unillustrated) are formed, and through these openings, the electrode pads 23 are exposed through the passivation film. The second semiconductor chip 20 has a thickness smaller than that of the first semiconductor chip 10 described above, and is formed substantially rectangular as seen in a plan view as shown in FIGS. 2 to 4. Moreover, the second semiconductor chip 20 has, as seen in a plan view, an area smaller than that of the first semiconductor chip 10 described above.

Here, in this embodiment, as shown in FIGS. 1 and 4, in a region in the upper surface of the first semiconductor chip 10 other than where the integrated circuit 12 is formed, a recess 14 is formed. The recess 14 is so sized that the second semiconductor chip 20 described above fits in to it. Specifically, the recess 14 has a depth d (see FIG. 1) of approximately 200 μm, and is formed substantially rectangular as seen in a plan view so as to correspond with the second semiconductor chip 20. Inside the recess 14, the second semiconductor chip 20 described above is disposed. As shown in FIG. 1, the second semiconductor chip 20 is fixed to the first semiconductor chip 10 (the floor surface of the recess 14) with an interlayer sealer 35, which is formed of die-bonding paste, polyimide, or the like, interposed such that the upper surface (the surface on which the integrated circuit 22 is formed, namely one main surface) of the second semiconductor chip 20 is level with the upper surface (the surface on which the integrated circuit 12 is formed, namely one main surface) of the first semiconductor chip 10.

The insulating layer 30 is formed, for example, of polyimide. The insulating layer 30 is, as shown in FIGS. 1 and 5, formed so as to cover the entire surface of the passivation film (unillustrated) and to fill the gap between the recess 14 and the second semiconductor chip 20. Moreover, in the insulating layer 30, through holes 30a are formed in positions facing the electrode pads 13 and 23 (see FIGS. 3 and 4) so as to expose the electrode pads 13 and 23 (see FIGS. 3 and 4) respectively.

The rewiring layers 31 are formed, for example, of a metal material such as copper. The rewiring layers 31, as shown in FIG. 5, are formed, on the upper surface of the insulating layer 30, so as to extend each from one through hole 30a to the position where the corresponding metal post 33 is provided. One end part of each rewiring layer 31 is electrically connected to an electrode pad 13 or 23 (see FIGS. 3 and 4) via a through hole 30a. The other end part of a rewiring layer 31 connected electrically to an electrode pad 23 on the second semiconductor chip 20 is, in the position where the corresponding metal post 33 is disposed, electrically connected to the other end of the corresponding rewiring layer 31 among the rewiring layers 31 connected electrically to the electrode pads 13 on the first semiconductor chip 10. This makes the integrated circuits 12 and 22 electrically connected together. Note that not all the electrode pads 23 on the second semiconductor chip 20 need to be connected electrically with electrode pads 13 on the first semiconductor chip 10.

The sealing resin layer 32 is formed, for example, of epoxy resin, etc. The sealing resin layer 32, as shown in FIGS. 1 and 3, is formed so as to cover the surfaces of the insulating layer 30 and the rewiring layers 31, and seals the upper surface (one main surface) of the first semiconductor chip 10 and the second semiconductor chip 20 in the semiconductor device. The sealing resin layer 32 also covers the side surfaces of the first semiconductor chip 10.

The metal posts 33 are formed of a metal material such as copper. The metal posts 33 are formed to have a substantially cylindrical shape, and are provided so as to penetrate the sealing resin layer 32 in its thickness direction as shown in FIG. 1. Moreover, the metal posts 33 are disposed in predetermined positions on the rewiring layers 31 and are thereby electrically connected with the rewiring layers 31.

In the semiconductor device according to the embodiment, as shown in FIG. 3, the metal posts 33 are disposed on each of the upper surface of the first semiconductor chip 10 and the upper surface of the second semiconductor chip 20. Among the plurality of metal posts 33, some (33a) are disposed substantially halfway between the electrode pads 13 on the first semiconductor chip 10 and the electrode pads 23 on the second semiconductor chip 20. To a metal post 33 (33a) so disposed, a rewiring layer 31 connected electrically to an electrode pad 23 on the second semiconductor chip 20 and a rewiring layer 31 connected electrically to an electrode pad 13 on the first semiconductor chip 10 are both electrically connected. This makes it possible, when the integrated circuit 12 and the integrated circuit 22 are electrically connected together via the rewiring layers 31, to shorten the length of the rewiring layers 31 from the electrode pads 13 on the first semiconductor chip 10 to the metal posts 33 and the length of the rewiring layers 31 from the electrode pads 23 on the second semiconductor chip 20 to the metal posts 33.

The solder balls 34 are, as shown in FIG. 1, provided so as to cover the parts of the metal posts 33 (parts of the upper surfaces (tips) of the metal posts 33) exposed through the sealing resin layer 32.

In this embodiment, by providing the recess 14 in the predetermined region in the first semiconductor chip 10 and disposing the second semiconductor chip 20 inside the recess 14 as described above, it is possible to prevent the semiconductor device from becoming thicker even when it is provided with a plurality of semiconductor chips. Thus, it is possible to make electronic devices slimmer.

In this embodiment, by forming the integrated circuit 12 on the first semiconductor chip 10 and forming the integrated circuit 22 on the second semiconductor chip 20 as described above, it is possible to form each circuit by a separate manufacturing process; thus, as distinct from in a case where the integrated circuits 12 and 22 are formed on a single chip (a case where a plurality of functions are integrated on a single chip), it is possible to prevent the manufacturing process from becoming complicated. It is therefore possible to easily enhance the performance of the integrated circuits 12 and 22 and to increase the manufacturing yield. Here, it is possible to employ a manufacturing process optimized separately for each semiconductor chip, and thus it is possible to easily optimize the integrated circuits 12 and 22. Therefore, in the semiconductor device according to the embodiment with the structure described above, it is possible to shorten its development period and, at the same time, to reduce its development cost. Moreover, it is possible to change specifications and add functions easily.

In the structure according to this embodiment described above, since the second semiconductor chip 20 is disposed inside the recess 14 in the first semiconductor chip 10, as in the three-dimensionally stacked semiconductor device, it is possible to reduce the mounting area of (the area occupied by) the semiconductor device.

In this embodiment, by configuring the integrated circuit 12 with, for example, a logic circuit, etc. and configuring the integrated circuit 22 with, for example, a memory, etc. as described above, it is possible to easily change part of specifications (e.g. change the specifications of the memory). In addition, by employing a general-purpose semiconductor chip as the second semiconductor chip 20 on which the integrated circuit 22 is formed, it is possible to easily reduce (cut down) the costs for development and manufacturing and to easily reduce the development period.

In this embodiment, by disposing the second semiconductor chip 20 inside the recess 14 in the first semiconductor chip 10 such that the upper surface of the first semiconductor chip 10 on which the integrated circuit 12 is formed is level with the upper surface of the second semiconductor chip 20 on which the integrated circuit 22 is formed as described above, it is possible to form a plurality of semiconductor chips like a single semiconductor chip; thus, it is possible to easily prevent the semiconductor device from becoming thicker and to easily reduce the mounting area of (the area occupied by) the semiconductor device. With this structure, even when the manufacturing processes of the integrated circuits 12 and 22 differ greatly, it is possible to easily fabricate a structure similar to that in which the integrated circuits 12 and 22 are formed on the upper surface of the first semiconductor chip 10. That is, it is possible to easily fabricate a structure similar to that in which a plurality of functional regions employing different manufacturing processes are formed on a single semiconductor chip. This makes it possible to improve the flexibility in design and to shorten the development period. Moreover, in the structure according to this embodiment described above, since the surface (the upper surface of the first semiconductor chip 10) on which the integrated circuit 12 is formed is level with the surface (the upper surface of the second semiconductor chip 20) on which the integrated circuit 22 is formed, it is possible to electrically connect the integrated circuits 12 and 22 together via the rewiring layers 13 easily.

In the semiconductor device according to this embodiment, since a plurality of semiconductor chips can be formed like a single semiconductor chip as described above, in a packaging process, etc. of a semiconductor chip, it is possible to perform packaging by a process similar to that in a case where a single semiconductor chip is employed.

In this embodiment, since the semiconductor device is formed in a WLCSP type package, it is possible to obtain a semiconductor device that can not only shorten the development period, but also can easily make electronic devices slimmer and can easily reduce the mounting area (occupied area).

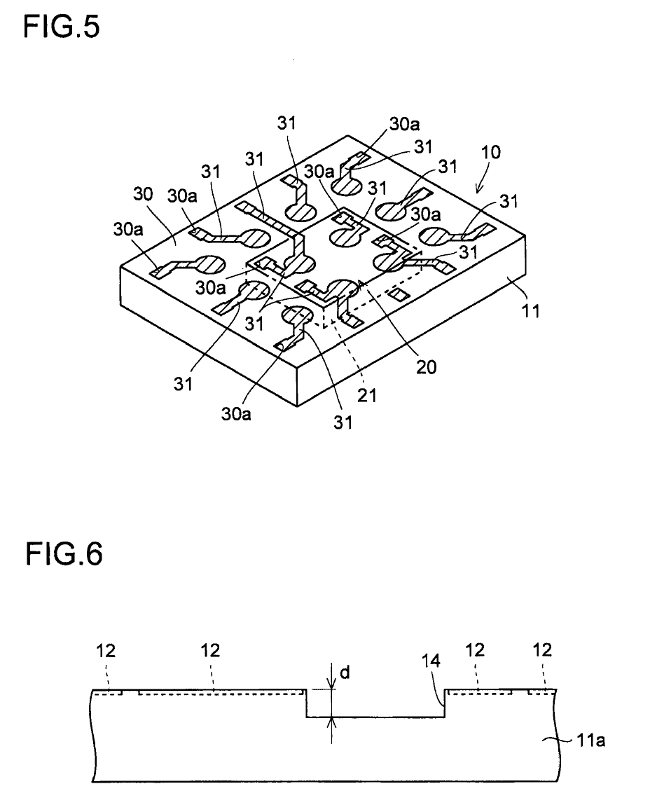

FIGS. 6 to 17 are sectional views illustrating a method of manufacturing the semiconductor device embodying the invention. A description will now be given of the method of manufacturing the semiconductor device embodying the invention with reference to FIG. 1 and FIGS. 3 to 17.

First, as shown in FIG. 6, an integrated circuit 12 is formed on the upper surface of a silicon substrate 11a. Here, the integrated circuit 12 is formed in a region other than where a recess 14 is formed. Next, in predetermined regions on the upper surface of the silicon substrate 11a, a plurality of electrode pads 13 (see FIG. 4) are formed, and an internal wiring layer (unillustrated) is formed to electrically connect the electrode pads 13 and the integrated circuit 12 together. Next, on the silicon substrate 11a, a passivation film (unillustrated) formed of silicon oxide or silicon nitride is formed. Then, by removing the region of the passivation film corresponding to the electrode pads 13, the surfaces of the electrode pads 13 are exposed through the passivation film.

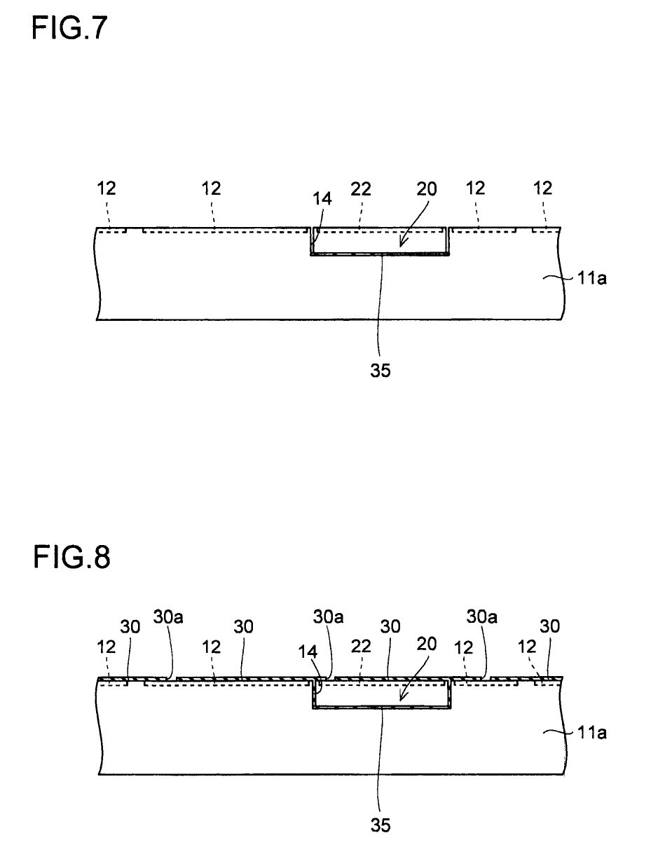

Then, by dry etching such as RIE (reactive ion etching), the recess 14 with a depth d of approximately 200 μm is formed in a predetermined region in the upper surface of the silicon substrate 11a. Note that the recess 14 described above may be formed before the integrated circuit 12 is formed. Next, as shown in FIGS. 4 and 7, a second semiconductor chip 20 on which an integrated circuit 22, electrode pads 23 (see FIG. 4), and a passivation film (unillustrated) are formed in advance is disposed inside the recess 14. Here, the second semiconductor chip 20 is fixed to the floor surface of the recess 14 with an interlayer sealer 35 formed of die-bonding paste, polyimide or the like, and is formed such that the upper surface of the second semiconductor chip 20 (the surface on which the integrated circuit 22 is formed) is level with the upper surface of the silicon substrate 11a (the surface on which the integrated circuit 12 is formed).

Next, as shown in FIG. 8, an insulating layer 30 formed of polyimide or the like is formed on the entire top surface of the silicon substrate 11a on which the second semiconductor chip 20 is disposed. Then, a predetermined region of the insulating layer 30 is removed by etching or the like. In this way, the insulating layer 30 is formed into a predetermined pattern and through holes 30a are formed in positions facing the electrode pads 13 and 23 (see FIGS. 3 and 4) so as to expose the electrode pads 13 and 23 (see FIGS. 3 and 4) respectively.

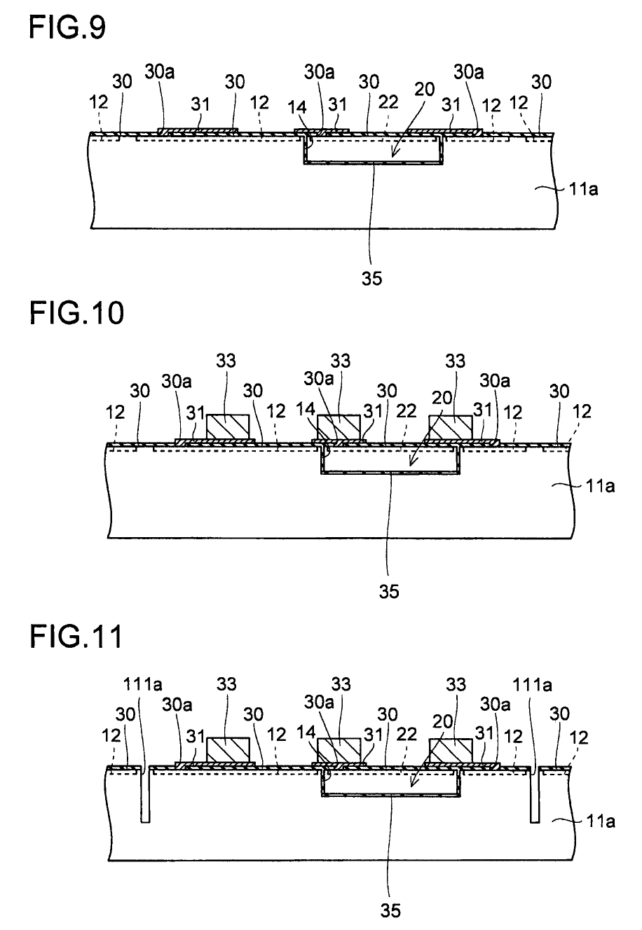

Thereafter, as shown in FIG. 9, a plurality of rewiring layers 31 with a predetermined pattern are formed on the upper surface of the silicon substrate 11a. The rewiring layers 31 are formed so as to be electrically connected with the electrode pads 13 and 23 (see FIGS. 3 and 4) via the through holes 30a and are formed such that some of the rewiring layers 31 electrically connect an electrode pad 13 and an electrode pad 23 together as shown in FIGS. 3 and 5. In this way, the integrated circuits 12 and 22 are electrically connected together via the rewiring layers 31.

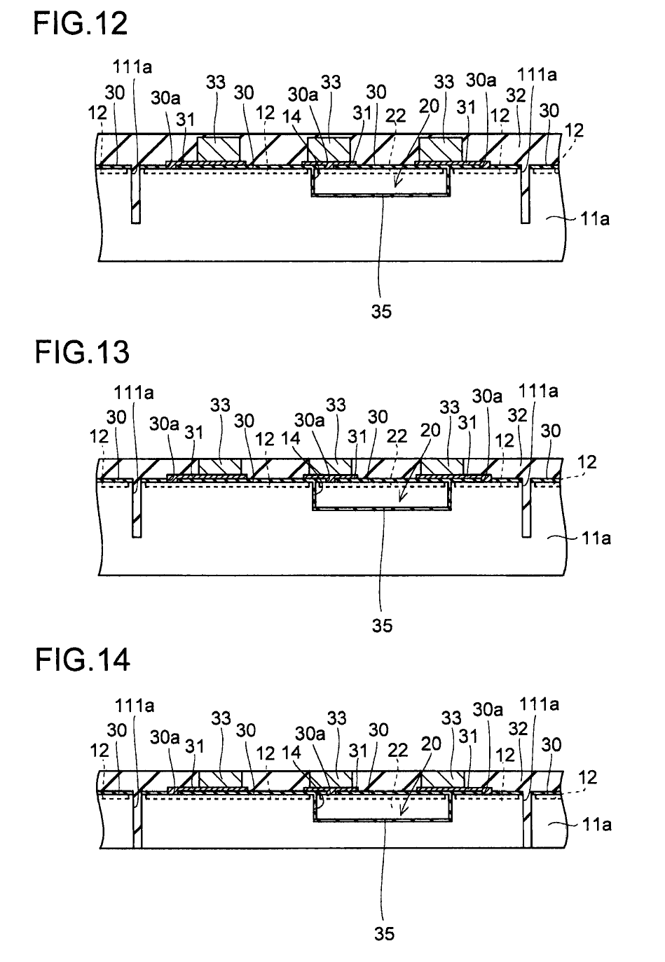

Next, as shown in FIG. 10, by plating or the like, a plurality of cylindrical metal posts 33 formed of a metal material such as copper are formed at predetermined positions on the rewiring layers 31. Then, as shown in FIG. 11, by use of a dicing saw (unillustrated) or the like, incisions 111a are formed from the upper surface of the silicon substrate 11a to halfway into its thickness in its thickness direction. Thereafter, as shown in FIG. 12, a sealing resin layer 32 formed of epoxy resin or the like is formed so as to cover the entire top surface of the silicon substrate 11a.

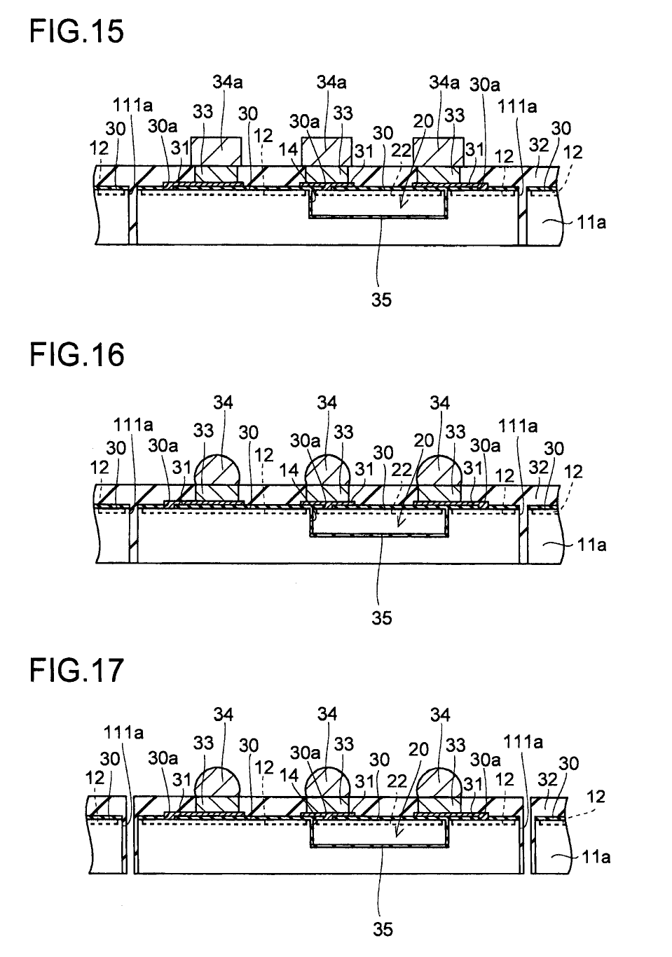

Next, polishing is performed from the sealing resin layer 32 side to expose the upper surfaces of the metal posts 33 through the sealing resin layer 32 as shown in FIG. 13. Next, polishing is performed from the bottom surface side of the silicon substrate 11a to reduce the thickness of the silicon substrate 11a to a thickness of approximately 490 μm as shown in FIG. 14. Then, as shown in FIG. 15, by printing or the like, solder layers 34a are formed on the upper surfaces of the metal posts 33 exposed through the sealing resin layer 32, and then the silicon substrate 11a on which the solder layers 34a are formed processed by reflow soldering. In this way, solder balls 34 as shown in FIG. 16 are formed on the metal posts 33. Lastly, by cutting along the incisions 111a with a dicing saw, as shown in FIG. 17, the silicon substrate 11a is divided into individual pieces. In this way, the semiconductor device embodying the invention shown in FIG. 1 is manufactured. Note that the first semiconductor chip 10 is obtained by the silicon substrate 11a being divided into individual pieces.

The embodiments disclosed herein are to be considered in all respects as illustrative and not restrictive. The scope of the present invention is set out in the appended claims and not in the description of the embodiments hereinabove, and includes any variations and modifications within the sense and scope equivalent to those of the claims.

For example, although the above-described embodiment deals with an example in which the second semiconductor chip is disposed inside the recess in the first semiconductor chip, this is not meant to limit the invention; it is also possible, instead, to form a plurality of recesses in the first semiconductor chip and to dispose other semiconductor chips inside the recesses other than where the second semiconductor chip is disposed. Moreover, it is also possible to form a recess having, as seen in a plan view, a relatively large area and to two-dimensionally dispose a plurality of semiconductor chips inside the recess.

Although the above-described embodiment deals with an example in which the solder balls, as external electrode terminals, are provided on the upper surface of both the first semiconductor chip and the second semiconductor chip, this is not meant to limit the invention; it is also possible, instead, to provide the solder balls on the upper surface of one of the first semiconductor chip and the second semiconductor chip.

Although the above-described embodiment deals with an example in which the present invention is applied to a WLCSP type semiconductor device, this is not meant to limit the invention; it is also possible to apply the invention, instead, to any semiconductor device other than a WLCSP type.

Although the above-described embodiment deals with an example in which the semiconductor device employs a single first semiconductor chip in which the second semiconductor chip is disposed inside the recess, this is not meant to limit the invention; it is also possible, instead, to form a three-dimensionally stacked semiconductor device by employing a plurality of first semiconductor chips in each of which a second semiconductor chip is disposed inside a recess. With this structure, it is possible to enhance the functions and the performance of the semiconductor device. Moreover, it is possible to reduce the number of the semiconductor chips laid on one another compared with a conventional three-dimensionally stacked semiconductor device, and thus it is possible to prevent the semiconductor device from becoming thicker.

Although the above-described embodiment deals with an example in which the integrated circuit on the second semiconductor chip is formed with a circuit having a different function from the integrated circuit on the first semiconductor chip, this is not meant to limit the invention; it is also possible, instead, to form the integrated circuit on the second semiconductor chip with a circuit having a similar function to the integrated circuit on the first semiconductor chip. Here, forming integrated circuit parts in which specification changes etc. are relatively frequent on the second semiconductor chip permits such specification changes, etc. to be made by changing the design of only the second semiconductor chip; thus it is possible to improve the flexibility in design and to shorten the development period. Moreover, it is possible to reduce the development cost.

What is claimed is:

1. A semiconductor device comprising:
a first semiconductor chip having an integrated circuit part formed on one main surface thereof and a recess formed in a region in the one main surface other than where the integrated circuit part is formed; and
a second semiconductor chip having an integrated circuit part formed on one main surface thereof,
wherein the second semiconductor chip is disposed inside the recess in the first semiconductor chip such that the one main surface of the second semiconductor chip is positioned on a same side as the one main surface of the first semiconductor chip.

2. The semiconductor device according to claim 1,
wherein the second semiconductor chip has a thickness smaller than a thickness of the first semiconductor chip.

3. The semiconductor device according to claim 1, further comprising:
a wiring conductor extending between the one main surface of the first semiconductor chip and the one main surface of the second semiconductor chip,
wherein the integrated circuit part of the first semiconductor chip and the integrated circuit part of the second semiconductor chip are electrically connected together via the wiring conductor.

4. The semiconductor device according to claim 1,
wherein a depth of the recess is set such that the one main surface of the first semiconductor chip is level with the one main surface of the second semiconductor chip.

5. The semiconductor device according to claim 1,
wherein an external connection terminal is formed on at least one of the one main surfaces of the first semiconductor chip and the second semiconductor chip.

6. The semiconductor device according to claim 5,
wherein the external connection terminal is formed on each of the one main surface of the first semiconductor chip and the one main surface of the second semiconductor chip.

7. The semiconductor device according to claim 1,
wherein the integrated circuit part on the first semiconductor chip and the integrated circuit part on the second semiconductor chip have different functions from one another.

8. The semiconductor device according to claim 1,
wherein a sealing resin layer is formed on the one main surface of the first semiconductor chip and on the one main surface of the second semiconductor chip.

9. The semiconductor device according to claim 8,
wherein the sealing resin layer is formed so as to cover at least part of a side surface of the first semiconductor chip.
